(19) United States
(12) Patent Application Publication
(10) Pub. No.: US 2007/0045785 A1
(43) Pub. Date: Mar. 1, 2007

(54) Reversible-multiple footprint package and method of manufacturing

(76) Inventor: Jonathan A. Noquil, Bislig (PH)

Correspondence Address: HISCOCK & BARCLAY, LLP, 2000 HSBC PLAZA, ROCHESTER, NY, 14604-2404, US

(21) Appl. No.: 11/215,485

(22) Filed: Aug. 30, 2005

(51) Int. Cl. H01L 23/495

(52) U.S. Cl. 257/666

(57) ABSTRACT

The lead frame 10 has drain leads 7 with first ends proximate one edge of the die pad and second ends distal from the die pad. A gate lead is proximate an opposite edge of the die pad and extends away from it. Source leads 6 are integral with the die pad and extend away from the same edge as the gate lead. After encapsulation the universal drain clip 30 is attached to the drain of the die and selectively attached to the distal ends of the drain leads. For landed grid footprints and ball grid footprints, the universal clip provides a drain contact on the same exterior surface as the source and gate contacts. For an MLP footprint, the universal drain is connected to the distal ends of the drain leads to carry the drain contact to the opposite external surface.

### BACKGROUND

Semiconductor devices must be packaged before they can be installed and used in an electronic products or systems such as cell phones, portable computers, personal digital assistants and others. Any package must accommodate the size and operation of the devices that they hold and consider several factors that impact the viability and longevity of the packaged device. These factors include the cost of the package and its mechanical and electrical characteristics.

One of the most efficient methods for packaging a device is encapsulating the device in an insulating material such as plastic resin. That method is widely used to package most commercial semiconductor devices. While ceramic packaging is preferred for some military and outer space environments, plastic packaging is by far the method of choice for commercial and industrial uses of semiconductors. Most plastic encapsulation is carried out by using a transfer molding process. It permits a manufacturer to simultaneously encapsulate hundreds of devices. In a typical molding process a number of semiconductor dies are attached to die attach pads of a lead frame. The lead frame may hold four to six or more dies between opposite side rails. Tie bars extend from the side rails to the die attach pad. Leads surround the die attach pad. For power semiconductor devices, the top of the die has source and gate bumps that attach to the leadframe. Portions of the leads extend outside the package. Some packages have prominent leads that extend into through holes in a printed circuit board. Other packages have smaller exposed leads and some packages are termed “leadless” because they merely expose the lower surface of a lead that has its upper surface wire bonded to the device.

Many semiconductor devices, especially power devices, generate heat. Unless the heat is removed from the package, the operation of the device may be impaired and in the case of extreme heat the device may fail. In order to remove heat from the device, others have proposed one or more arrangements for attaching a heat sink, often knows as a clip, to the packaged device in order to remove heat.

Semiconductor devices are packaged in a variety of different packages. Each package may have its own footprint. Often the footprint of one type of package is different from others types. For example, the footprint of a landed grid array package is different from a ball grid array and both of them are different from a molded leadless package (MLP). Each of the package types may be adapted to receive a chip that is uniquely fashioned to accommodate the type of package. Often the heat sink clip is attached to the device before encapsulation and must be affixed with a heat resistant material capable of withstanding the high temperature of the molten encapsulating resin. Attaching a clip prior to encapsulation adds further steps to an already complex process. The heat sink clips are often placed in a metal press that imposes a bend or other configuration into the clip. The bending machines impose undesired stresses in the clip. During encapsulation and other high temperature processing, the internal stresses in the clip may cause the clip to detach from the device.

One popular example of a flip chip with a copper clip is shown in U.S. Pat. No. 6,870,254. There a packaged semiconductor device includes a leadframe that has source and gate connections, a bumped die including solder bumps on a top side that is attached to the leadframe such that the solder bumps contact the source and gate connections. A copper clip attaches to the backside of the bumped die such that the copper clip contacts drain regions of the bumped die and a lead rail. The device is manufactured by flip chipping a bumped die onto the leadframe. It has a v-groove and the copper clip is bent at one end to fit into the v-groove of the lead frame. The process involves reflowing the solder bumps on the bumped die and solder paste that is placed between the copper clip and the backside of the bumped die. Thus, the clip and bumps are separately formed, the manufacturing process requires two reflow operations and there is only one footprint associated with the disclosed device. See also U.S. Pat. No. 6,777,800 that also requires two reflow operations and a bent clip. Both patents are incorporated by reference.

Another package with a clip attached is found in US Publication 2003/0075786. That reference shows a leaded molded package with exposed bottom and top sides. A drain clip has a contoured or bent edge that is attached to the drain of a semiconductor device. It too requires two reflow operations and has only one footprint. Its disclosure is also incorporated by reference.

See also U.S. Pat. No. 6,867,481. This is an example of a flip chip device with a clip. A single footprint is disclosed and the clip is bent thereby providing a longer electrical path that increases internal resistance.

Other manufacturers use bent clips and attach the clip prior to encapsulation. See FIG. 12 as an example of on such device. A die 202 has solder paste 203 for soldering the die to the lead frame 201. A source bridge 204 connects the source regions on the top of the die to the source leads. The bridge 204 is soldered to the leads with solder paste 206. After soldering, the assembly is encapsulated in a molding compound 207.

### SUMMARY

The invention overcomes one or more problems posed by the prior art and provides a flexible, modular approach to packaging devices with different footprints using common elements. Where the prior art would use different lead frames, heat sinks, and two or more solder pastes for assembling and packaging semiconductor devices, the invention uses one lead frame, one clip and one type of solder paste to assemble and package devices with two or more different footprints. By the unique combination of lead frame and universal drain clip, the invention achieves a substantial reduction in the number of components needed to assemble and package different devices and a reduction in the number of process steps to package such devices. The elements of the invention enable assembling and packaging a device to have a land grid array footprint or a ball grid array footprint or an MLP footprint with all external contacts on one surface of the molded package.

In its broader aspects, the invention provides a package for a semiconductor that has source and gate regions on a first surface and a drain region on as second surface. The fist surface has an array of source and gate contacts and the second, opposite surface has a drain contact. The device is mounted on a lead frame that can be used to provide one of two or more footprints. The leadframe has a die attach pad that receives and holds the die on the lead frame. In particular, the source array of contacts on the die are attached to the die pad. The lead frame also has one or more elongated drain leads. Proximate ends of the drain leads are adjacent the die attach pad and distal ends of the drain leads are remote from the die attach pad. The lead frame has elongated source and gate leads with proximate ends adjacent the die attach pad and distal ends remote from the die attach pad. In general, the drain leads extend from one edge of the die pad and the source and gate leads extend from an opposite edge. One feature of the lead frame is that the distal ends of the leads are disposed in a first plane and the proximate ends of the leads are disposed in a second plane spaced from the first plane. In particular, the proximate ends of the leads are in the same plane as the die attach pad. The source contacts on the die are attached to the die attach pad. The assembled die and leadframe are molded in an insulating resin. The molding operation leaves certain areas of the die, lead frame and leads exposed for post-encapsulation processing. A thermal and electrical conductive clip is attached to the exposed drain surface of the die. The conductive clip may, as in two footprint embodiments, provide an external contact to the drain of the device. As an alternative, the clip may be used to reroute the drain contact to the opposite side of the finished package and thereby provide a third footprint embodiment. The clip is spaced from the distal ends of the source and gate leads and extends over the distal ends of the drain leads and is selectively in mechanical and electrical contact with the drain leads of the leadframe.

In a landed grid array footprint, distal ends of the source and gate leads are untouched and thus provide exposed raised lands for source and gate connection after the device is encapsulated. In the ball grid array footprint, the distal ends of the source and gate leads are half etched. The half etched ends are coated with solder paste and ball contacts are formed on the exposed, pasted half etched ends. In the MLP footprint, proximate ends of the drain leads are exposed to thereby provide external drain connections on same outside surface of the package as the source and gate external connections.

The process of assembly, encapsulation and post clip attachment are substantially the same for all three footprints. The only variation is that the distal ends of source and gate leads are half etched to provide a ball contact footprint. After the die is attached to the die pad, the assembled device is encapsulated in a transfer molding operation. The mold is designed to leave selected surfaces exposed in accordance with the selected footprint. The bottom or drain surface of the die is exposed to receive the conductive clip. The clip and the die attach pad together provide electrical connections as well as thermal conduction to remove heat from the die.

As a result, the invention provides flexible package components and process steps that may be used for two or more product footprints. The invention reduces the cost of packaging and reduces the stress in the clip because the clip is not bent. Other savings are achieved by reducing the number of solder paste to only one and by effectively eliminating lead from the soldering operation. Reliability of the package device is improved and internal resistance is reduced by shorter current paths. The clip provides dual heat sinks for three footprints.

### DRAWINGS

FIG. 1a is a sectional view of a semiconductor device.

FIG. 1b is a partial plan view of the device shown in FIG. 1a.

FIG. 1c is top perspective view of the leadframe.

FIG. 1d is a bottom perspective view of the leadframe.

FIG. 2a is a sectional view of a packaged device having a first footprint.

FIG. 2b is a plan view of the top of the device of FIG. 2a.

FIG. 2c is a plan view of the bottom of the device of FIG. 2b.

FIGS. 3a-3h are sectional views of a process for assembling and packaging a semiconductor device having a first footprint.

FIGS. 4a, 4b are top and bottom perspective views respectively of a packaged device having a first footprint.

FIG. 5a is a sectional view of a packaged device having a second footprint.

FIG. 5b is a plan view of the bottom of the device of FIG. 5a.

FIGS. 6a, 6b 4b are top and bottom perspective views respectively of a packaged device having a second footprint.

FIG. 7a is a sectional view of a packaged device having a third footprint.

FIG. 7b is a plan view of the top of the device of FIG. 7a.

FIG. 7c is a plan view of the bottom of the device of FIG. 7b.

FIGS. 8a, 8b 4b are top and bottom perspective views respectively of a packaged device having a third footprint.

FIGS. 9a-9g are sectional views of a process for assembling and packaging a semiconductor device having a third footprint.

FIG. 10a is a perspective view of a low cost drain clip.

FIG. 10b is a perspective view of a modified low cost drain clip with grooves adapted for the first or second footprints.

FIG. 10c is a perspective view showing how the clip of FIGS. 10a or 10b attaches to a packaged device.

FIG. 10d is a sectional view of the device shown in FIG. 10c.

FIG. 11a is a perspective view of a low cost drain clip modified to have stamped leads.

FIG. 11b is a further modification of FIG. 11a where grooves are added.

FIG. 11c is a perspective view a packaged semiconductor device assembled with the clip of FIG. 11a or FIG. 11b and adapted for the MLP footprint.

FIG. 12 is a cross section view of a device with a source clip attached before molding.

### DETAILED DESCRIPTION

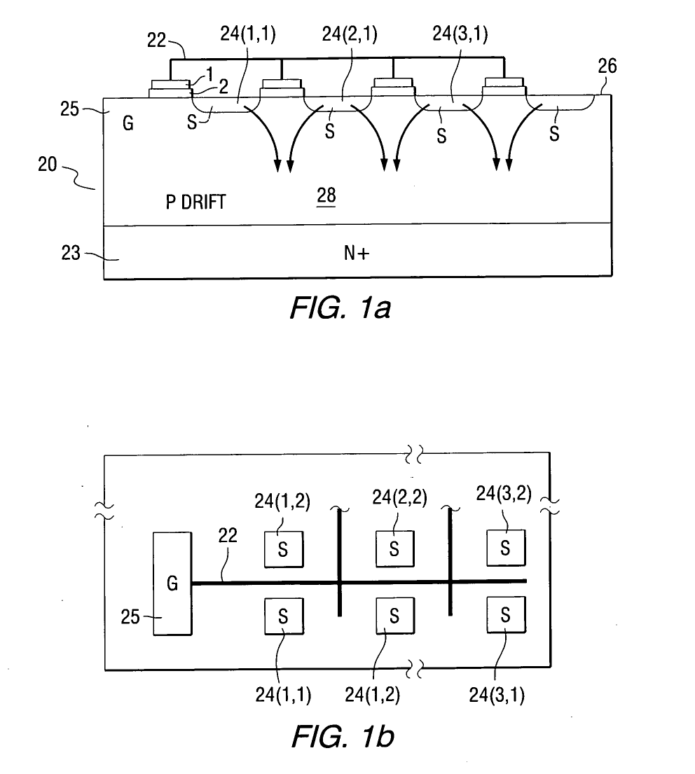

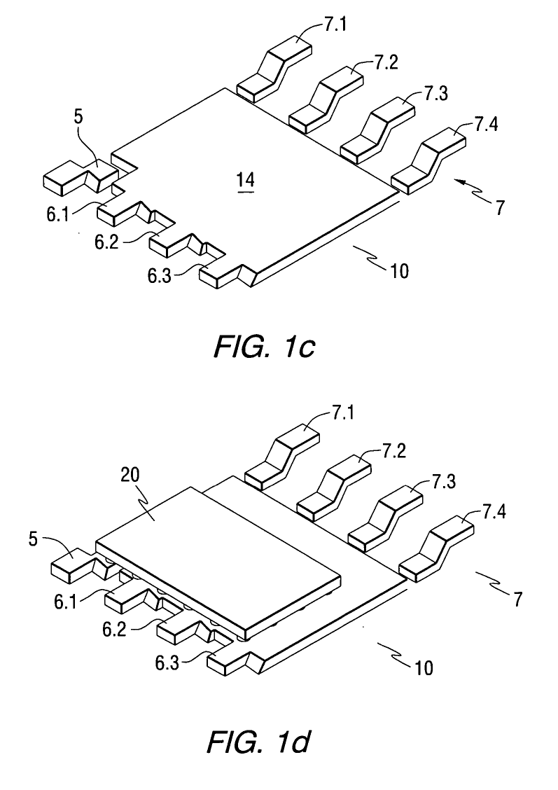

With reference to FIGS. 1a and 1b, a semiconductor device 20 is shown. The device is typical mosfet. It is constructed on a substrate of monocrystalline silicon or other suitable semiconductor material. The exemplary device is a single n-type transistor with a gate structure 25 and source regions 24 on one surface 26 and a drain region 23 on the other surface 27. The gate structure includes a gate runner 22 that has a conductive upper layer 1 and insulating lower layer 2. The source regions 24 form an array in the surface 26 of the substrate. The source regions are highly doped n-type regions that are disposed in a lightly doped p-type drift region 28. The gate runner 22 extends among and between adjacent source regions and controls the flow of current between the source array and the drain region 23. That region is also heavily doped with n-type dopants. In operation, current generally flows vertically in the device between the sources and the drain. The vertical current is controlled by the gate runners that are disposed between adjacent sources.

Those skilled in the art understand that the device 20 may have any one of a number of structures, layers and diffusions well known to such skilled artisans. Although the device 20 has a surface gate structure, those skilled in the art understand that the gate structure may be disposed in trenches and such trench gated devices have relatively higher density compared to surface gated devices. The device 20 may be constructed using p-type dopants and thus becomes a p-type mosfet. The device may also represent any type of semiconductor device that has two terminal contacts on one surface and a third terminal contact on the other surface, including and not limited to bipolar transistors with an emitter, base and collector and other three terminal devices such as insulated gate bipolar transistors. The invention may be further adapted by devices with four or more terminals or to integrated circuits.

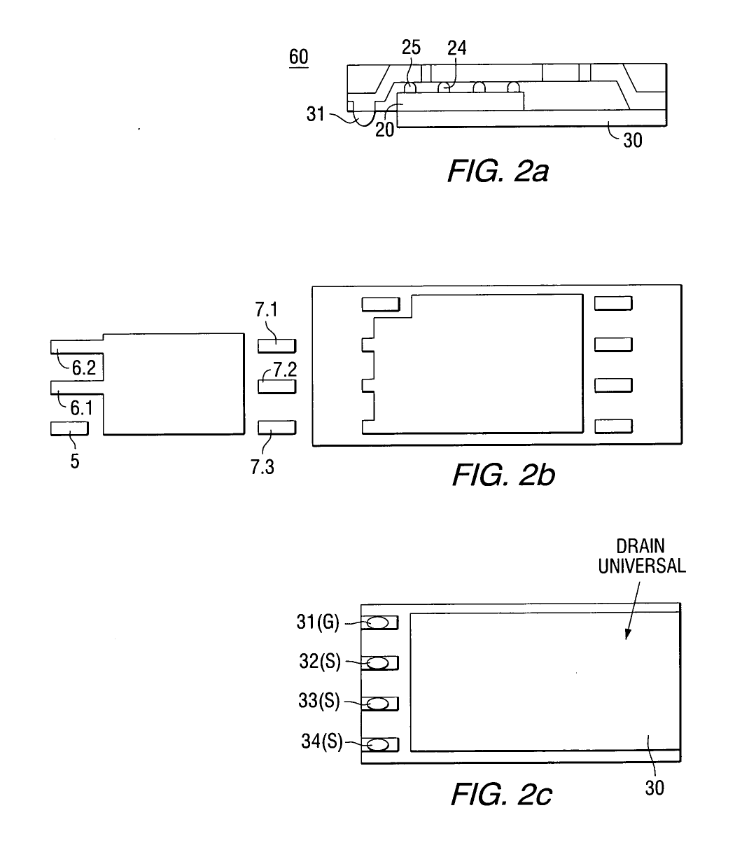

A first embodiment of the invention is shown in FIGS. 2a, 2b, 2c. There the packaged semiconductor device 60 has a semiconductor die 20 with ball-typed external contacts 31. The die 20 has a first surface 26 with source and gate contacts 21. The lead frame 10 has a die attach pad 14 that is attached to the source contacts 21 on the first surface 26 of the die.

Turning to FIGS. 1c and1d, the leadframe has at least one gate lead 5 that is electrically isolated from the other leads and from the die attach pad 14. It also has a plurality of source leads 6.1, 6.2 . . . 6.n. The source leads 6.1 -6.n are normally integral with the die attach pad 14. The drain leads 7.1, 7.2, 7.3, . . . 7.n are also electrically isolated from the other leads 5, 6 and from the die attach pad 14. The leads 11 have distal ends 12 that are spaced from the die attach pad and proximate ends 13 that are adjacent the die attach pad. The distal ends 12 are generally disposed in a common plane 42 that is spaced from the plane of the die attach pad 14. The proximate ends 13 are generally disposed in a common plane 43 together with the die attach pad 14. An angled member 18 extends between the distal and proximate ends and is generally disposed at an obtuse angle with respect to the plane of the die attach pad 14. The angle may be a right angle or an acute angle, if so desired.

At least one gate contact 25 is connected to the gate lead 5 which is electrically isolated from the source leads and the drain leads. The source ball bump contacts are attached to the die attach pad 14. The drain 23 is attached to a conductive clip 30 made of copper, copper alloy or other suitable electrical and thermal conductive material. Note that the clip 30 also lies in substantially the same plane as the distal ends of the leads but is spaced from the source and gate distal ends and is connected to the distal ends of the drain leads. One end of the clip 30 is connected to the drain leads 7 of the lead frame. An insulating molded resin 16 encapsulates the device 20 and the lead frame 10 and leaves exposed the lower surface of the distal ends of the source and gate leads and the drain leads. The outer surface of the clip is also exposed and thereby facilitates transfer of heat away from the die 20.

With reference to the bottom view of FIG. 2c, one may see that all the external terminals that connect to the die 20 are on one side of the packaged device 60. The clip 30 provides the drain contact and the exposed distal ends of the source and gate leads 5, 6 provide the external electrical contacts to the source and gate contacts on the die 20.

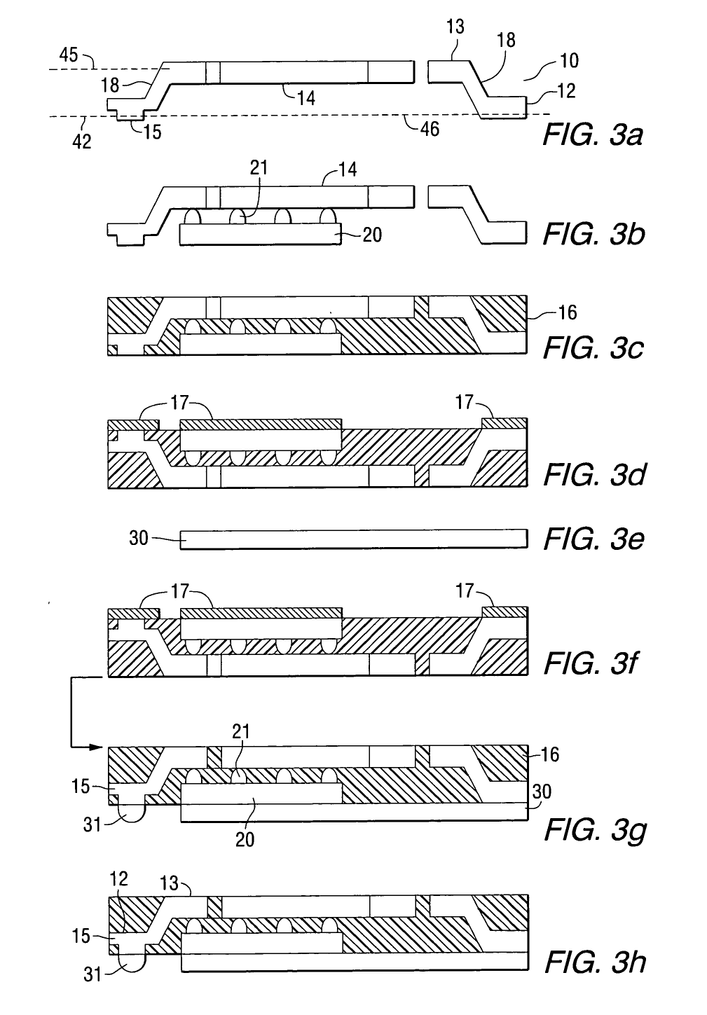

A series of steps for making the device 60 is shown in FIGS. 3a-3h. The following steps may be used to fashion a packaged semiconductor device with a land grid array of external terminals or a ball grid array. The steps of the process are substantially the same except that the normal, flat distal ends of the source and gate leads are half etched to accept ball-type contacts. If a land grid array is desired, the half etching step is omitted.

In a first step and leadframe 10 is provided with die attach pad 14 and leads 11 that extend from first ends 13 proximate the die attach pad to second ends 12 distal from the die attach pad 14. The leadframe 10 is a half etched leadframe that has a portion of the distal ends of the source and gate leads, 6, 5 etched away to provide ball contacts (or grids in the case of land grid type) 15 on the distal ends. Those skilled in the art understand that the single lead 10 shown in the FIG. 3a and in other figures is part of an array of leads that are temporarily held together by side rails (not shown) and tie bars (not shown).

As shown in FIG. 3b, a semiconductor die 20 is attached to the die attach pad 14 of the leadframe 10. Assembly of the die 20 on the die pad 14 is conventional. A pick and place machine uses a vacuum chuck to remove a die from a diced wafer, apply adhesive to the pad 14 and then attach the die 20 to pad 14. The source ball-type contacts 21 are mechanically and electrically connected to the die pad 14 and the at least one ball-type gate contact 25 is connected to the gate lead 5.

After die attach, the assembled lead frame 10 and die 20 are placed into a mold and the mold is placed in a transfer-molding machine. The mold holds multiple assembled leadframes and dies, perhaps one or more hundred such assemblies. After the mold is locked in the transfer-molding machine, hot, liquid plastic insulating resin is forced under pressure into the mold. Runners carry the molten resin to the individual mold cavities holding the assemblies and each assembly becomes encapsulated in resin 16 as shown in FIG. 3c.

The assemblies are removed from the mold. The mold cavity is designed to leave exposed the land (or ball pad in the case of a ball grid type) grids of the leadframe on the ends of the source and gate leads. The ball grids 15, the second surface 27 of the die 20 and the distal ends of the drain leads 7 Tare exposed. Those exposed surfaces are coated with a single solder paste 17 as shown in FIG. 3d.

Next the conductive clip 30 is attached to the assembly. The clip 30 has a rectangular configuration and is flat on both surfaces. This is an advantage compared to other clips that have a bent or contoured configuration. The invention provides a clip that is easier to manufacture and to assemble and is less prone to separation from the die. Unlike conventional bent or contoured clips, the invention does not require expensive bending equipment and a conventional stamping machine can produce clips for the invention. The clip of the invention has little or no internal stress because it is not bent. This is an advantage during assembly and operation because clips with bends may detach from the die due to the stored internal stresses. For example, during singulation the assembled, packaged devices on the lead frame array are separated from each other by severing the tie bars that connects the leadframes to the side rails. Separation is performed by a saw or a punch. The impact of the punch or the torque of the saw when combined with the stored internal stress of the bent clip may cause the bent clip to detach from the device. In sharp contrast, the invention's clip has to such stresses and thus is less prone to separate from the die during singulation.

One end of the clip covers the drain and the second surface 27 of the die and the other end of the clip covers the distal ends of the drain leads 7. The paste 17 is sufficiently adhesive to hold the conductive clip 30 in place during soldering where the clip is permanently attached to the die 20 and a solder bump or balls 31 are formed on the half etched ball grids 15. See FIG. 3g. This step saves significant time and effort because in a single step the manufacturer not only forms the ball grid contacts, but also attaches the clip 30 to the device 20. Normally the steps of ball formation and clip attachment are separate steps and require different materials. The completed, packaged semiconductor product 60 is shown in FIG. 3h.

In the case of a lead (Pb) free package, an advantage of the invention with clip 30 (using post-encapsulation attachment) is that the clip may be attached at the same melting point as the flip chip inter-connect paste and thus may use the same Pb-free paste. Clip 30 is attached and reflowed without directly affecting the flip chip inter-connect. Other prior art techniques place the clip just after the flip chip process and the clip needs another type of paste, which has to have lower in melting point in order not to re-melt the flip-chip joint. The process step of the invention is a low temperature, lead free reflow process utilizing the same paste compositions. The flat clip 30 combined with the recessed die attach pad 14 provides heat sinks on both sides of the device 20. The die attach pad 14 is disposed along the top surface of the packaged device and the clip 30 is on the other surface. Hence, both surfaces are available to conduct heat away from the die 30.

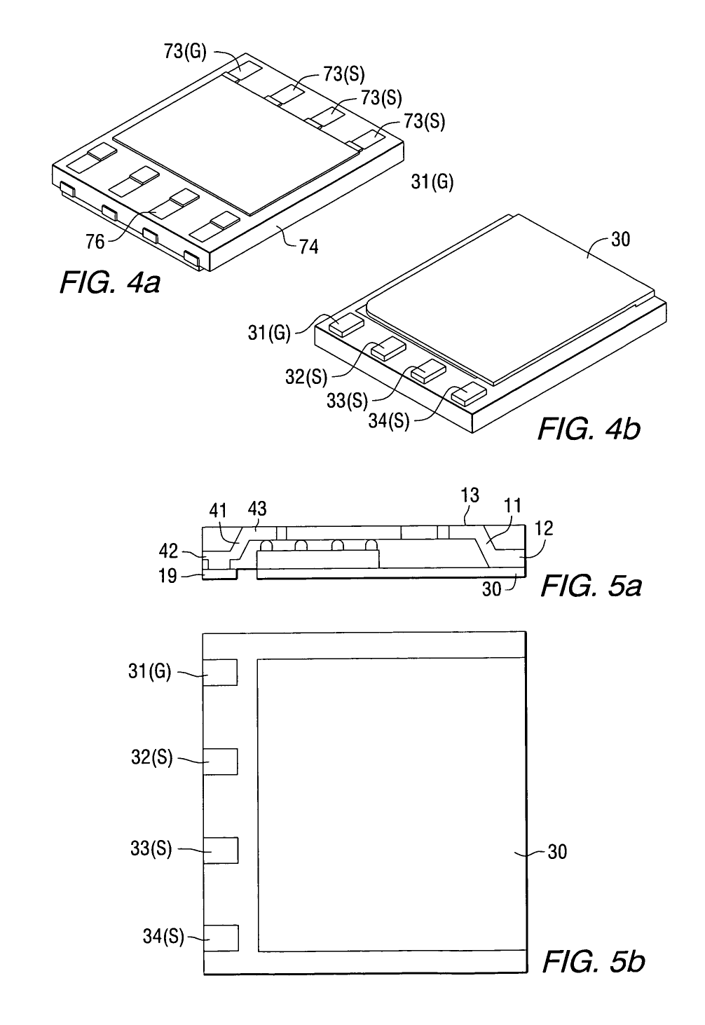

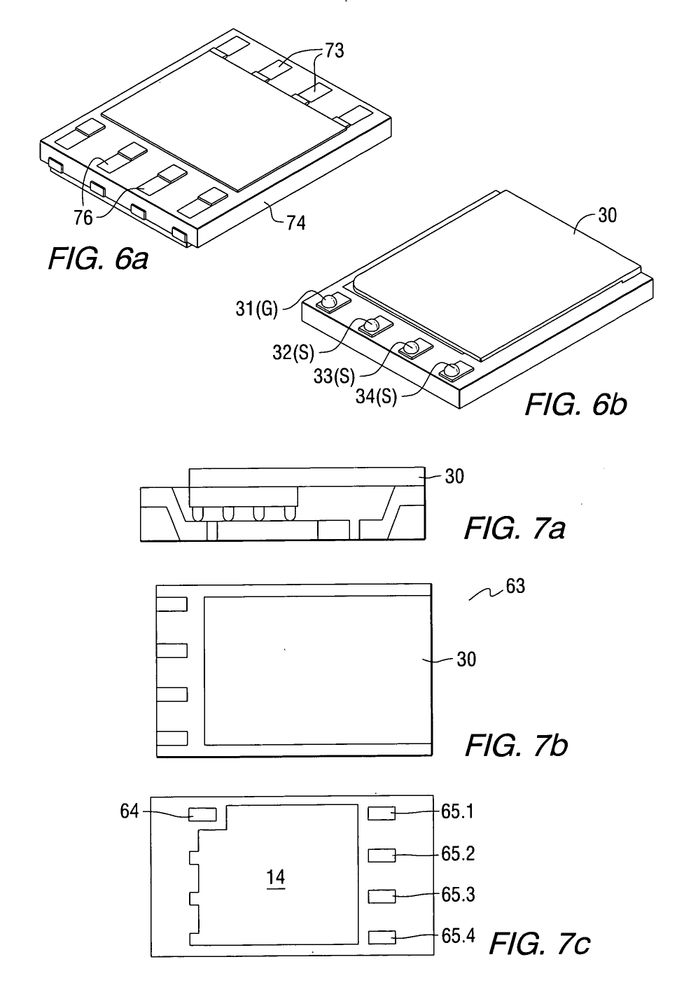

Top and bottom perspective views of the land grid array embodiment 60 as found in FIGS. 4a, 4b. The invention provides two sets of contacts so that a manufacturer may elect to have a conventional set of contacts as shown in FIG. 4b (Land Grid type) or 6b with Crossection view in FIG. 5a, or an alternate set of contacts as shown in FIG. 4a (Crossection shown in FIG. 7a). When the manufacturer elects the conventional set of contacts shown in FIG. 4b or 6b, the proximate ends 13 of the leads are covered with insulating material leaving the die pad 14 exposed paving the way for better heat spreading (top side cooling).

In the case of an MLP type footprint in reference to the top and bottom views of the first embodiment which are shown in FIGS. 4a, 4b, the top view become the mounting footprint (FIG. 4a) and the bottom clip would now serve as drain routing and at the same time a HeatSink. The proximate ends of the drain leads 76 and the proximate ends of the gate lead and source leads 73(G), 73(S) are extended with solderable and highly conductive polymer (Manufactured by dow coming). Extension are done to the edge of the compound hence it turns the compound to be solderable. This now patterned the conventional MLP footprint. The polymer is adheres well to the compound and part of the leads 76, 73(G/S).

There cases that some customers need to utilize the bottom side of the package for circuit lay-outing including via holes, the die attach pad 14 can be covered with a solder mask 74 that can electrically insulates the die attach pad from the underside circuits and via holes.

One of the key features of the invention is its ability to adapt a common set of components and a common set of process steps to two or more footprints. By the term “footprint” we mean the exterior dimensions for a packaged device that is to become part of an electronic system. For example, several popular footprint packages include landed grid packages (described above), ball grid packages and molded leadless package (MLP). The above embodiment of FIGS. 2 and 3 is compatible with the footprint of not only with the ball grid type package, but also with the landed grid version. The following discussion will show how the invention meets the requirements of the ball grid array and then the discussion with show how a third footprint, the molded leadless package (MLP) is also met by the invention.

The ball grid array footprint embodiment is shown in FIGS. 5a, 5b, 6a, 6b. These figures are virtually identical to FIGS. 2a, 2c, 4a, 4b except that the external terminals on the source and gate leads have flat, land type connections rather than ball-type connections. The process for making the package shown in FIGS. 6a, 6b is the same process shown in FIGS. 4a, 4b.

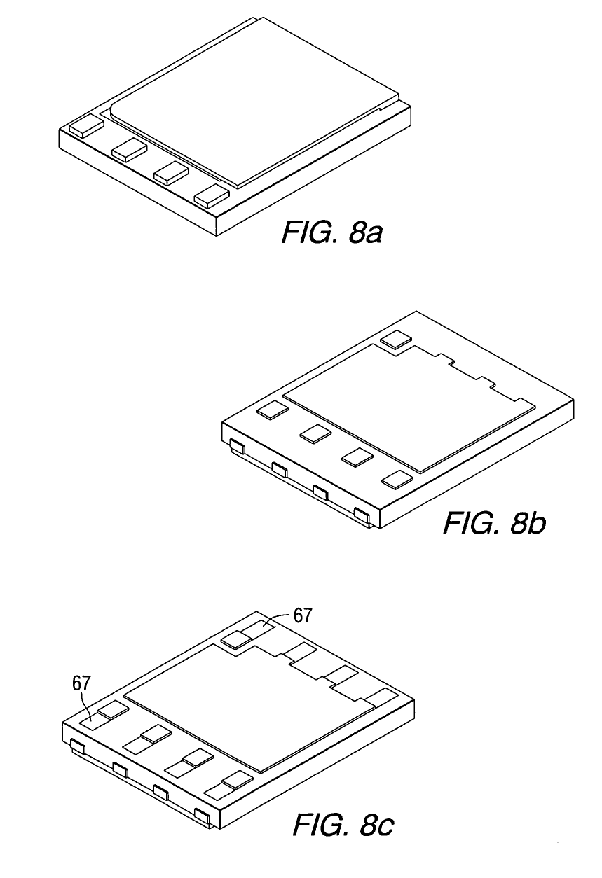

A third embodiment is shown in FIGS. 7a-7b. This is the MLP embodiment where the drain leads are used to carry the drain contact to the same side of the external package as the source and gate leads and thereby meet the requirements for a MLP footprint. In the package 63 the top side has the clip 30 that acts as a heat sink and the distal ends of the leads are covered with an insulating coating. The bottom surface of the package 63 has at least one gate contact 64, a large source contact (in the form of die attach pad 14) and drain contacts 65.1-65.4 provided by the distal ends of the drain leads that carry the electrical contact for the drain to the same surface as the electrical contacts for the source and gate. As shown in FIG. 8c the bottom side contacts are printed with a solder mask 66 and conductive, solderable polymer 67 to extend the contacts from the exposed proximate ends of the leads to the distal edges the packaged device.

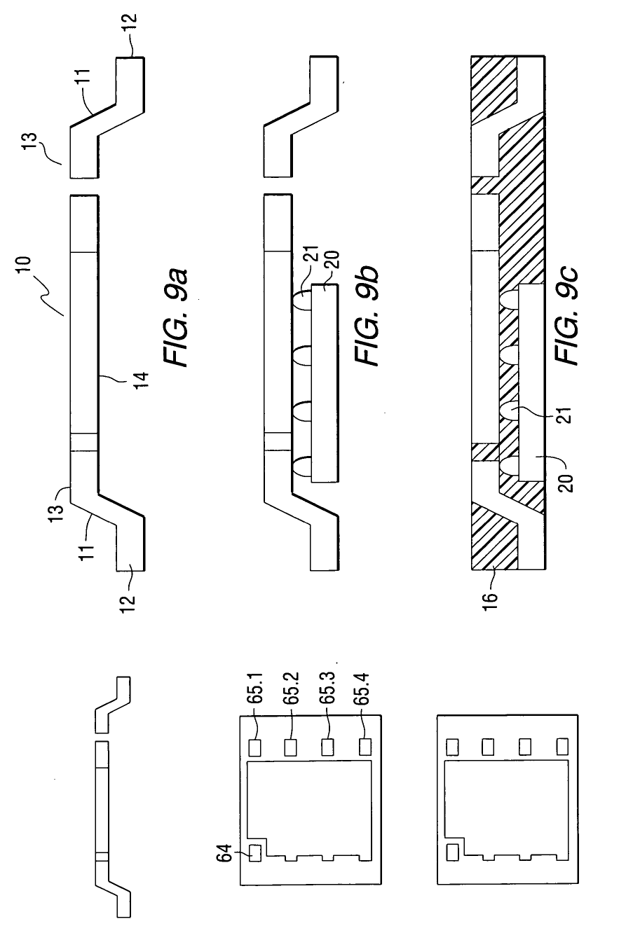

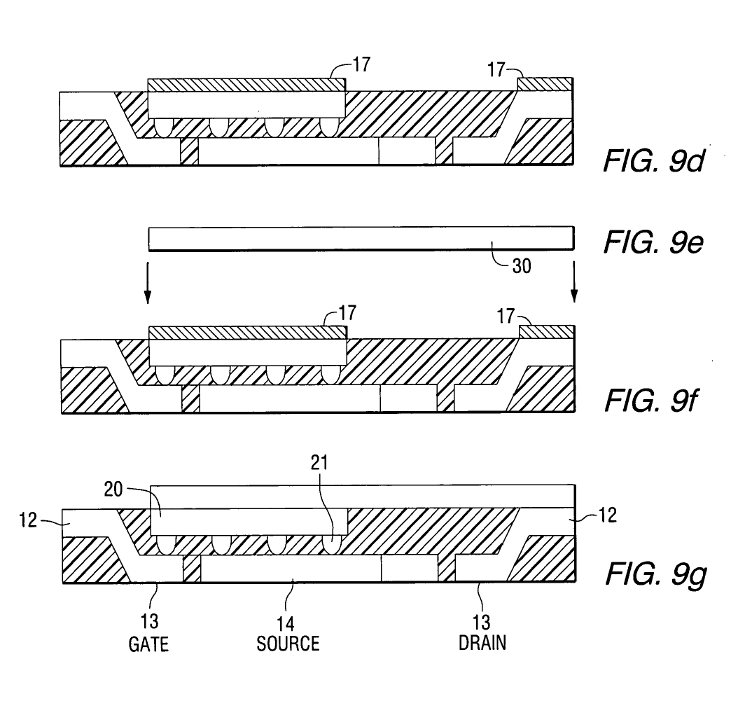

The process for making the MLP footprint embodiment 63 is shown in FIGS. 9a-9g. A lead frame 10 with a recessed die attach pad 14 and multiple leads with distal and proximate ends is provided. A semiconductor die 20 is attached to the pad 14 (FIG. 9b) and the assembled device is molded with encapsulating resin 16 (FIG. 9c). Then a common paste 17 is applied to the drain surface of the device 20 and to the distal ends of the drain leads 65.1-65.4. A planar, rectangular conductive clip 30 is held on the die attach pad and the distal ends by the paste 14. The assembly is reflowed to permanently attach the clip to the package. The bottom of the package has all the external terminals of the device 20 including a gate terminal 13, a source terminal (pad 14) and drain terminals, the proximate ends of the drain leads.

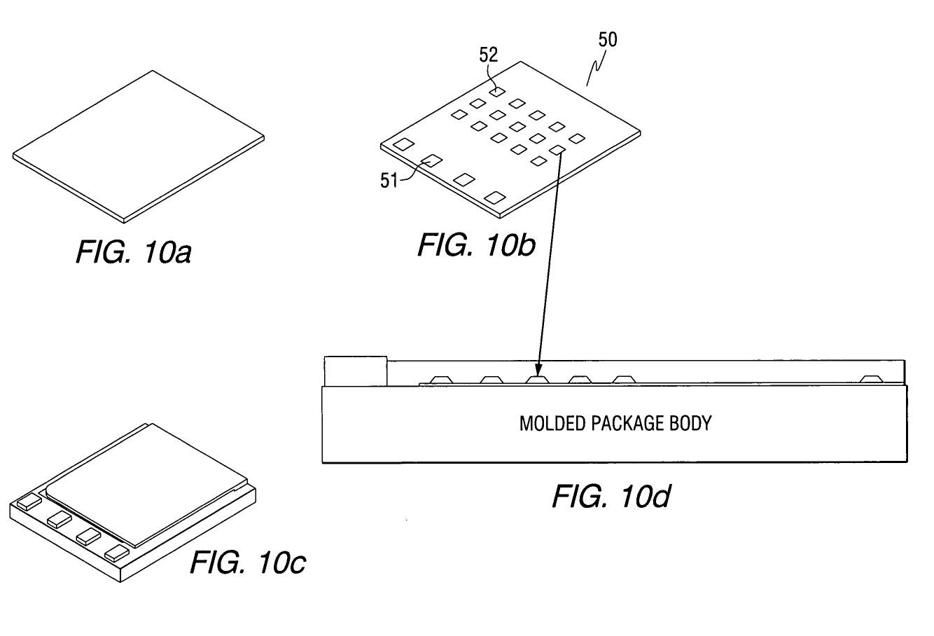

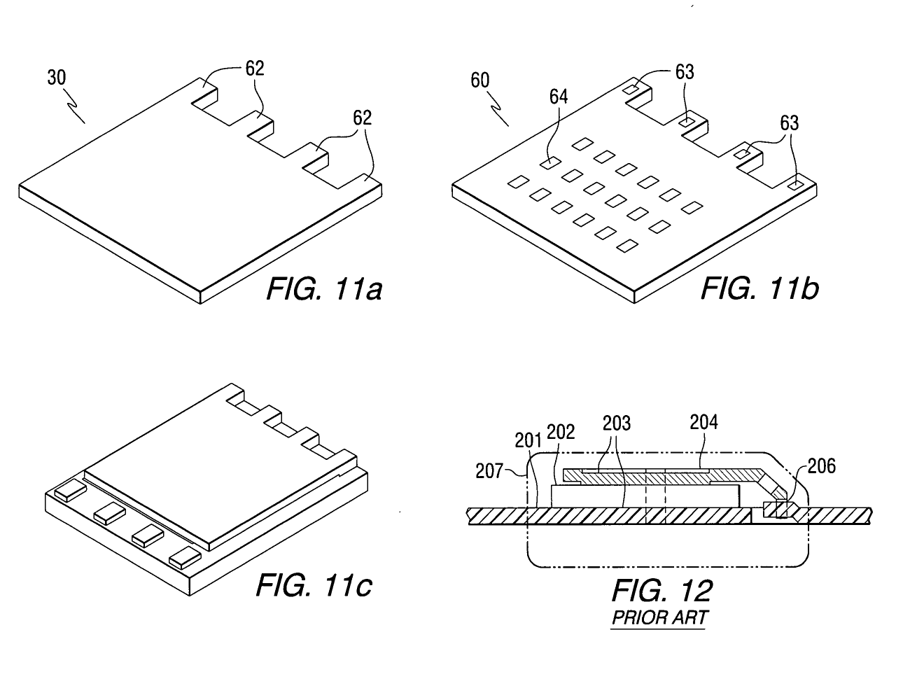

Turning to FIGS. 10a and 10b, one may compare the basic, low cost drain clip 30 with a modified drain clip 50. That modified clip has grooves 51 along one edge and an array of grooves 52 in the central area. The grooves 51, 52 correspond to the locations of the distal ends of the drain leads and the source—gate array on the first surface 26 of the die, respectively. The target depth of the grooves is about 50 microns and the grooves improve the reliability of the mechanical and electrical contact between the clip 50 and the die and the leads. The grooves are made by a simple stamping operation which is inexpensive and does not impose significant stress in the clip 50. The grooves on the die pad 14 correspond to the locations of the source bumps.

A similar improved clip 60 is provided for the MLP footprint. In one improvement the clip 60 is stamped to remove material along one edge and form drain fingers 62. The fingers and the central portion of the clip are stamped again at the same or later time, to add grooves 63, 64 to the fingers and the body of the clip, respectively.

Having thus disclosed several embodiments and modifications of the invention, those skilled in the art will understand that further changes, additions, omissions, alterations and substitutions to the elements and steps of the embodiment may be made without departing from the spirit and scope of the appended claims.

1. A package for a semiconductor device comprising:
a device having an first and second surfaces, an array of source and gate contacts on the first surface, and a drain contact on the second surface;
a leadframe having
a die attach pad for receiving and holding a semiconductor die,
elongated drain leads having proximate ends adjacent the die attach pad and distal ends remote from the die attach pad; and
elongated source and gate leads having proximate ends adjacent the die attach pad and distal ends remote from the die attach pad;
wherein the distal ends of the all the leads are disposed in one plane and the proximate ends of all the leads are disposed in another plane space from the one plane;
a conductive clip attached to the planar drain contact, spaced from the distal ends of the source and gate leads and extending over the distal ends of the drain leads;
an insulating molded resin encapsulating the device and the leadframe and leaving exposed selected distal or proximate ends of the leads and leaving exposed the second surface of the conductive clip.

2. The semiconductor package of claim 1 wherein the conductive clip is connected to the distal ends of the drain leads.

3. The semiconductor package of claim 2 wherein the distal or proximate ends of the source and drain are exposed on a first outside surface of the package.

4. The semiconductor package of claim 2 wherein the clip covers the distal ends of the drain leads.

5. The semiconductor package of claim 1 further comprising ball terminals or land terminals on exposed ends of the source and gate leads.

6. The semiconductor package of claim 1 wherein the clip has a plurality of grooves in its surface that faces the semiconductor device.

7. The semiconductor package of claim 1 wherein the clip has a plurality of fingers along one edge.

8. The semiconductor package of claim 7 wherein the fingers and a central portion of the clip have grooves.

9. A device having an first and second surfaces, an array of source and gate contacts on the first surface, and a drain contact on the second surface;
a leadframe having
a die attach pad for receiving and holding a semiconductor die,
elongated drain leads having proximate ends adjacent the die attach pad and distal ends remote from the die attach pad; and
elongated source and gate leads having proximate ends adjacent the die attach pad and distal ends remote from the die attach pad;
wherein the distal ends of the all the leads are disposed in one plane and the proximate ends of all the leads are disposed in another plane space from the one plane;
a conductive clip attached to the planar drain contact, spaced from the distal ends of the source and gate leads and covering the distal ends of the drain leads;
an insulating molded resin encapsulating the device and the leadframe and leaving exposed the distal ends of the source and gate lead, and
ball type terminals on the exposed source and gate leads.

10. The semiconductor package of claim 9 wherein the clip has a plurality of grooves in its surface that faces the semiconductor device.

11. The semiconductor package of claim 9 wherein the clip has a plurality of fingers along one edge.

12. The semiconductor package of claim 11 wherein the fingers and a central portion of the clip have grooves.

13. A device having an first and second surfaces, an array of source and gate contacts on the first surface, and a drain contact on the second surface;
a lead frame having
a die attach pad for receiving and holding a semiconductor die,
elongated drain leads having proximate ends adjacent the die attach pad and distal ends remote from the die attach pad; and
elongated source and gate leads having proximate ends adjacent the die attach pad and distal ends remote from the die attach pad;
wherein the distal ends of the all the leads are disposed in one plane and the proximate ends of all the leads are disposed in another plane space from the one plane;
a conductive clip attached to the planar drain contact, spaced from the distal ends of the source and gate leads and covering the distal ends of the drain leads;
an insulating molded resin encapsulating the device and the leadframe and leaving exposed the distal ends of the source and gate lead, and
land type terminals on the exposed source and gate leads.

14. The semiconductor package of claim 13 wherein the clip has a plurality of grooves in its surface that faces the semiconductor device.

15. The semiconductor package of claim 13 wherein the clip has a plurality of fingers along one edge.

16. The semiconductor package of claim 15 wherein the fingers and a central portion of the clip have grooves.

18. A device having an first and second surfaces, an array of source and gate contacts on the first surface, and a drain contact on the second surface;
a lead frame having
a die attach pad for receiving and holding a semiconductor die,
elongated drain leads having proximate ends adjacent the die attach pad and distal ends remote from the die attach pad; and
elongated source and gate leads having proximate ends adjacent the die attach pad and distal ends remote from the die attach pad;
wherein the distal ends of the all the leads are disposed in one plane and the proximate ends of all the leads are disposed in another plane space from the one plane;
a conductive clip attached to the planar drain contact, spaced from the distal ends of the source and gate leads and covering the distal ends of the drain leads;
an insulating molded resin encapsulating the device and the leadframe and leaving exposed the proximate ends of all leads.

19. The semiconductor package of claim 18 wherein the clip has a plurality of grooves in its surface that faces the semiconductor device.

20. The semiconductor package of claim 18 wherein the clip has a plurality of fingers along one edge.

21. The semiconductor package of claim 20 wherein the fingers and a central portion of the clip have grooves.

22. A method for assembling and packaging a semiconductor device having first and second surfaces, an array of raised source and gate contacts on the first surface, and a planar drain contact on the second surface comprising:
providing a lead frame having a die attach pad and source, gate and drain leads, said drain leads disposed adjacent one end of the die attach pad and electrically isolated from the die pad and the source and gate leads and terminating in a set of drain contact pads, and the source and gate leads at the other end of the die attach pad and terminating in source and gate contact pads;
assembling the die onto the lead frame by attaching the raised source and gate leads of the die to the die attach pad and to the source and gate leads;
encapsulating the assembled die and leadframe by molding the assembly in an insulating resin to form a package with one surface having regions exposing the drain contact of the die and the source and gate contact pads at the ends of the source and gate leads;
solder patterning the surface with exposed contact and contact pads;
attaching a clip to the exposed drain contact; and
reflowing solder to provide raised terminals on the exposed contact pads and to connect the clip to the drain and to the drain contact pads.

23. The process of claim 22 wherein the leads are half etched and the raised terminals on the leads are ball type terminals.

24. The process of claim 22 wherein the raised thermals on the leads are landed terminals.

25. The process of claim 22 further comprising the step of placing a plurality of grooves in a surface of the clip facing the semiconductor device.

26. The process of claim 22 further comprising the step of placing a plurality of fingers along one edge of the clip.

27. The process of claim 26 further comprising the step of placing grooves in the fingers and a central portion of the clip.

28. A method for assembling and packaging a semiconductor device having first and second surfaces, an array of raised source and gate contacts on the first surface, and a planar drain contact on the second surface comprising:
providing a leadframe having a die attach pad and source, gate and drain elongated leads,
said elongated drain leads disposed adjacent one end of the die attach pad, electrically isolated from the die pad and having proximate and distal drain contact pads at opposite ends of the drain leads, the source and gate leads and terminating in a set of drain contact pads, and
said elongated source and gate leads at the other end of the die attach pad and terminating in source and gate contact pads;
assembling the die onto the leadframe by attaching the raised source and gate leads of the die to the die attach pad and to the source and gate leads;
encapsulating the assembled die and lead frame by molding the assembly in an insulating resin to form a molded package with one surface having regions exposing the drain contact of the die and the distal drain contact pad, and the other surface of the molded package having exposed regions corresponding to the source and gate contact pads and the proximate drain contact pad;
solder patterning the surface with exposed contact and distal drain contact pads;
attaching a clip to the exposed drain contact and to the distal drain contact pads; and
reflowing solder to connect the clip to the drain and to the distal drain contact pads so that the other surface of the package has exposed source, gate and proximate drain contact pads.

29. The process of claim 28 further comprising the step of placing a plurality of grooves in a surface of the clip facing the semiconductor device.

30. The process of claim 28 further comprising the step of placing a plurality of fingers along one edge of the clip.

31. The process of claim 30 further comprising the step of placing grooves in the fingers and a central portion of the clip.
